(19) United States
(12) Patent Application Publication
(10) Pub. No.: US 2014/0183456 A1
(43) Pub. Date: Jul. 3, 2014

(54) BLUE LIGHT-EMITTING IRIDIUM COMPLEX AND APPLICATION FOR ORGANIC LIGHT EMITTING DIODE

(71) Applicant: Chien-Hong CHENG, (US)

(72) Inventors: Chien-Hong CHENG, Hsinchu (TW); Ho-Hsiu CHOU, Hsinchu (TW); Yi-Kai LI, Hsinchu (TW)

(73) Assignee: Chien-Hong CHENG, Hsinchu (TW)

(21) Appl. No.: 13/729,877

(22) Filed: Dec. 28, 2012

(51) Int. Cl. H01L 51/00

(52) U.S. Cl. CPC H01L 51/0085
USPC 257/40; 546/4

(57) ABSTRACT

An iridium complex is represented the following formula:

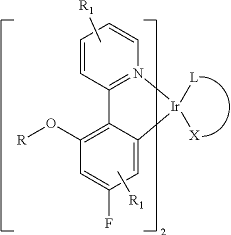

wherein each R₁ is independently hydrogen or a C₁-C₆ alkyl group, a C₁-C₆ alkoxy group, a hydroxyl group or a halogen, R is C1-C20 alkyl, C2-C20 alkenyl, C2-C20 alkynyl, C3-C20 cycloalkyl, C3-C20 cycloalkenyl, C1-C20 heterocycloalkyl, C1-C20 heterocycloalkenyl, aryl or heteroaryl; and a bidentate ligand is presented by L and X linked with an arch. The iridium complex is a blue light-emitting material and may function as a host emitter or a dopant in an OLED. An OLED using the iridium complex is also herein disclosed.

### BACKGROUND OF THE INVENTION

1. Field of the Invention

The present invention relates to a novel iridium complex and organic light emitting diode using the same, particularly to BLUE LIGHT-emitting iridium complexes and organic light emitting diode using the same.

2. Description of the Prior Art

Organic light-emitting diode (OLED) is an electronic device which emits light through the use of organic semiconductor materials and emitting materials. OLED works on the principal of electroluminescence, where a bias is applied to an electrode pair causing the electrons and holes to diffuse through an electron transport layer (ETL) and hole transport layer (HTL), respectively, to enter an emitting material region. The electrons and holes recombine in the emitting region and form a particle generally referred as exciton. In order for the exciton to come back to the ground state, the energy is given off in the form of photo radiation. The color of the radiation can be tuned by using different emitting materials.

Recently, organic emitting materials with an emissive triplet state, also referred to as organic phosphorescent materials, have drawn much attention as an OLED material. Theoretically, phosphorescent materials are three times in efficiency compared to conventional fluorescent materials which have an emissive singlet state. Common organic compounds have either no phosphorescent properties or can only be observed at a very low temperature, such as 77 K. Investigation has suggested that addition of heavy atoms can overcome this drawback; however, not all heavy atoms are suitable for this purpose. Researchers have reported that transition metals such as rhenium (Re), osmium (Os), iridium (Ir) and platinum (Pt) are the most suitable candidates.

Metal complexes have been used as the phosphorescent dopants of OLEDs. In some metal complexes, the presence of heavy atoms causes strong spin-orbital coupling, leading to the mixing of the singlet and triplet excited states. This greatly reduces the lifetime of the triplet state and the phosphorescence efficiency is promoted. Among these metal complexes used in the light-emitting layer of the organic light emitting diode, iridium complexes have been extensively researched due to the strong spin-orbit coupling resulting from their electron configurations.

Cyclometalated iridium complexes are the one of the most efficient and bright organic phosphorescent materials currently known. Among them, Iridium(III) bis(4,6-difluorophenylpyridinato)picolate (FIrpic) is a common blue phosphorescent material having triplet state. FIrpic renders high device efficiency, but its color saturation is poor. Its CIE coordination locates in the region around (0.16, 0.30). The high Y value leads to a color that lies between blue and green, rather than a deep blue color which is required in a full-color display.

In summary, blue phosphorescent material plays an important role in whether OLED can applied in the next generation white lighting. Therefore, a blue phosphorescent material having high external quantum efficiency, great hue, brightness and saturation is mostly desired by the industry.

### SUMMARY OF THE INVENTION

The present invention is directed to light-emitting iridium complexes and organic light emitting diode using the same.

According to one embodiment, an iridium complex is represented the following formula:

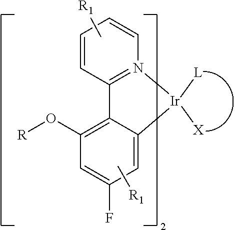

wherein each R₁ is independently hydrogen or a C₁-C₆ alkyl group, a C₁-C₆ alkoxy group, a hydroxyl group or a halogen, R is C1-C20 alkyl, C2-C20 alkenyl, C2-C20 alkynyl, C3-C20 cycloalkyl, C3-C20 cycloalkenyl, C1-C20 heterocycloalkyl, C1-C20 heterocycloalkenyl, aryl or heteroaryl; and
a bidentate ligand is presented by L and X linked with an arch, and has formula of Ar₁-Ar₂, wherein Ar₁ and Ar₂ independently are an aromatic ring or N-heterocyclic ring, or Ar₁-Ar₂ together are

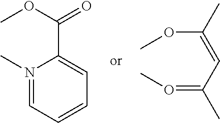

wherein L is N or O, and X is C, N or O.

According to another embodiment, an organic light emitting diode includes a cathode, an anode, an emitting layer and an organic material layer. The emitting layer is configured between the cathode and the anode, wherein the emitting layer comprises the aforementioned iridium complex.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIG. 1 is a schematic diagram illustrating an OLED device containing iridium complex.

### DESCRIPTION OF THE PREFERRED EMBODIMENT

The present invention is directed to iridium complexes and organic light emitting diodes using the same.

Referring to Formula (I), iridium complexes of the present invention are illustrated.

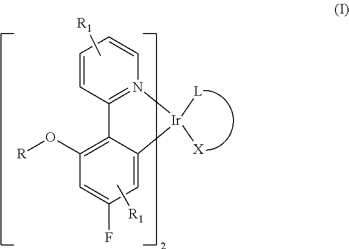

Each R₁ is independently hydrogen or a C₁-C₆ alkyl group, a C₁-C₆ alkoxy group, a hydroxyl group or a halogen. R is C1-C20 alkyl, C2-C20 alkenyl, C2-C20 alkynyl, C3-C20 cycloalkyl, C3-C20 cycloalkenyl, C1-C20 heterocycloalkyl, C1-C20 heterocycloalkenyl, aryl or heteroaryl. An auxiliary ligand is presented by L and X linked with an arch, and has formula of Ar₁-Ar₂, wherein Ar₁ and Ar₂ independently are an aromatic ring or N-heterocyclic ring, or Ar₁-Ar₂ together are

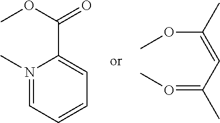

L may be N or O, and X may be C, N or O and the auxiliary ligand may be ĈN, ĈO, N̂N, N̂O, ÔO bidentate ligands. Examples and synthesis protocol of auxiliary ligands has been listed in US patent application Publication No. 20110313161 of Chi et al. and hence may be incorporated by reference.

In one preferred embodiment, the auxiliary ligand presented by L and X is represented with following formulae:

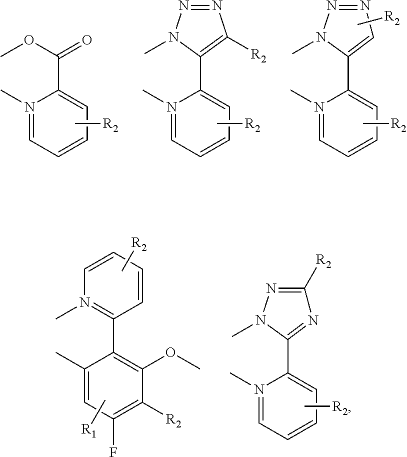

wherein R₂ is a member independently selected from the group consisting of hydrogen, halo, cyano, trifluoromethyl, amino, C1-C10 alkyl, C2-C10 alkenyl, C2-C10 alkynyl, C3-C20 cycloalkyl, C3-C20 cycloalkenyl, C1-C20 heterocycloalkyl, C1-C20 heterocycloalkenyl, aryl and heteroaryl.

In another preferred embodiment, the iridium complex of the present invention may be represented by the following formula:

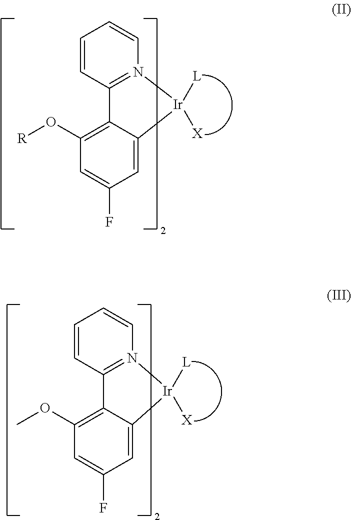

The preparation scheme for iridium complexes of formula (III) is listed as following:

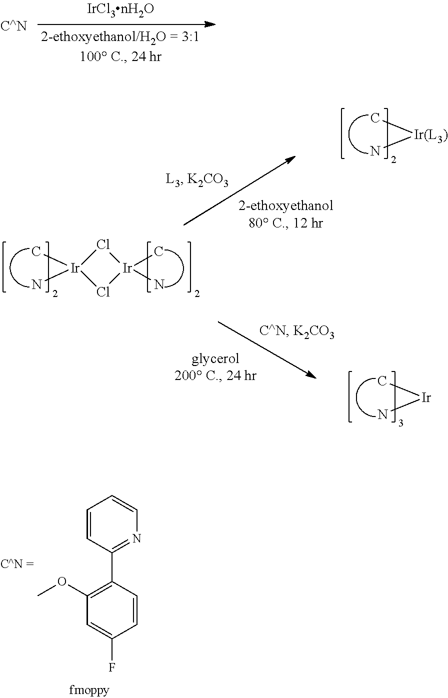

Examples of iridium include fmoppy₂Ir(pic), fmoppy₂Ir(pypz), fmoppy₂Ir(tfpytz), fmoppy₂Ir(tfpypz), fmoppy₂Ir(pytz), Ir(fmoppy)₃ respectively having exemplary auxiliary ligand L₃ listed below.

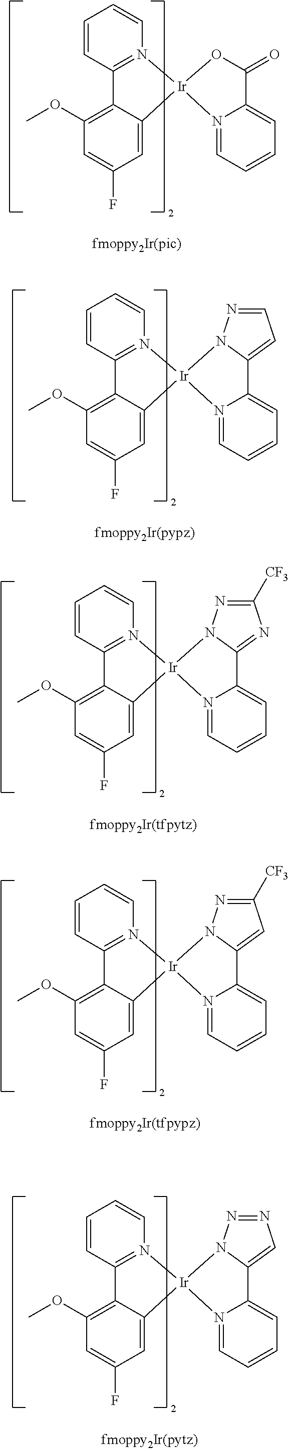

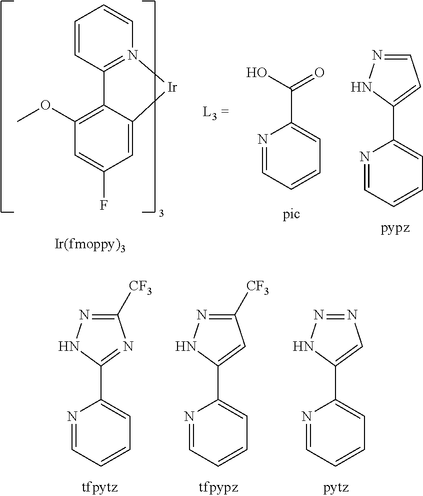

The detailed synthesis of exemplary iridium complexes of the present invention is now provided.

### Example 1

### Synthesis of Ligand fmoppy

The cyclometalating ligand fmoppy was obtained from the Suzuki coupling of 4-fluoro-2-methoxyphenylboronic acid with 2-bromopyridine using a Pd(0) complex as the catalyst. Acetone (10 mL), 2-bromo-5-fluorophenol (1.1 mL, 10 mmol) and CH₃I (0.93 mL, 15 mmol) was added to a flask containing K₂CO₃ (2.4 g, 17 mmol). After the mixture was stirred for 24 h at 40° C., acetone was removed by rotary evaporator and the residue was extracted with ether. The organic layer was washed with anhydrous MgSO₄ and the solvent was removed under vacuum to give the desired pale-yellow liquid, 1-bromo-4-fluoro-2-methoxybenzene. Then n-butyllithium (4.4 mL, 11 mmol, 2.5 M in hexane) was added dropwise to a stirred solution of 1-bromo-4-fluoro-2-methoxybenzene (2.1 g, 10 mmol) in anhydrous tetrahydrofuran (40 mL) at −78° C. under a nitrogen atmosphere. After stirring at −78° C. for 1 h, trimethoxylborate (2.2 mL, 20 mmol) was added and the solution was stirred for further 12 h at room temperature. NH₄Cl was added to the reactant to quench the reaction, then the solution mixture was extracted with CH₂Cl₂. The organic layer was collected and concentrated under reduced pressure. The white solid 4-fluoro-2-methoxyphenylboronic acid was obtained in 90% yield. Adding 4-fluoro-2-methoxyphenylboronic acid (1.0 g, 6.0 mmol), Pd(PPh₃)4 (0.034 g, 0.030 mmol), 2-bromopyridine (0.63 mL, 6.6 mmol), K₂CO₃ (14 mL, 1 M), and THF (22 mL) into a 100 mL flask. After the mixture was heated to 60° C. for 12 hours, the mixture was extracted with ethyl acetate. The organic layer was collected and removed the solvent to afford the desired compound fmoppy (yield=60%). ¹H NMR (400 MHz, CDCl₃, δ): 8.66 (d, J=4.4 Hz, 1H), 7.76-7.72 (m, 2H), 7.68 (t, J=7.6 Hz, 1H), 7.18 (t, J=6.8 Hz, 1H), 6.76 (t, J=8.4 Hz, 1H), 6.70 (dd, J=11.0, 2.0 Hz, 1H), 3.83 (s, 3H). ¹³C NMR (100 MHz, CDCl₃, δ): 164.92, 162.46, 157.97, 155.00, 149.17, 135.53, 132.08, 124.69, 121.48, 107.30, 99.23, 55.53. HRMS (EI, m/z): calcd for C₁₂H₁₀FNO: 203.0746; found M⁺ 203.0753.

Synthesis of N̂N Auxiliary Ligands

### Example 2

### Synthesis of pypz

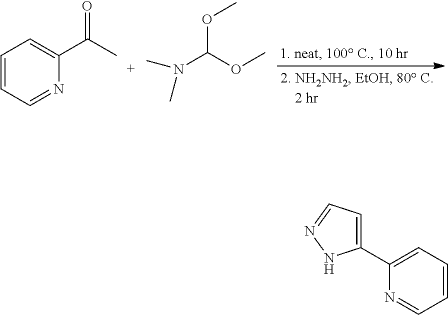

2-acetylpyridine(1.10 mL, 10 mmol) and N,N-dimethylformamide dimethyl acetal(1.99 mL, 15 mmol) were added to 50 ml flask with thermal reflux under 100° C. After completion of reaction, the organic layer extracted with CH₂Cl₂ was collected and condensed to obtain pale yellow solid. The obtained pale yellow solid was then dissolved with ethanol and heat and refluxed for 2 hours in the presence of excessive hydrazine.

After completion of reaction, the ethanol was dried in vacuum and the mixture was purified by column chromatography with n-hexane and ethyl acetate(40:60) as an eluent to afford the desired white solid pypz (yield=70%).

### Example 3

### Synthesis of tfpypz

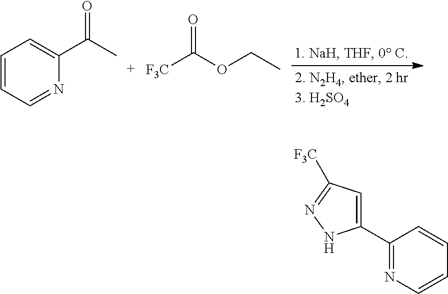

NaH (2.0 g, 83 mmole) was added and purged with nitrogen in a 150 ml two-neck flash. 50 ml anhydrous THF was then added and ethyl trifluoroacetate (4.26 g, 30 mmol) was added in an ice-bath. After the mixture was then slowly added with 2-acetylpyridine (3.63 g, 30 mmol), the ice-bath was then removed. After reaction for 8 hours at room temperature, the reaction mixture was quenched with water and adjusted to be weak-acidic with HCl. After condensation to remove THF, the mixture was extracted with CH₂Cl₂ and water and then condensed to obtain a reactive intermediate. The obtained product (2 mmol) was dissolved with 40 ml ethyl ether and then slowly added with NH₂NH₂ (0.13 g, 4 mmol). After reflux reaction under 40° C. for 2 hours, the ethyl ether was removed and a second intermediate of white precipitate was obtained with CH₂Cl₂ and n-hexane. The second intermediate was dissolved with 40 ml ethanol and added with 0.3 mL concentrated H₂SO₄. After heated and refluxed for 4 hours, the mixture was dried to remove ethanol solvent, dissolved with water and adjusted to become alkaline with K₂CO₃. The solution was then extracted with CH₂Cl₂ and condensed to obtain pale yellow solid. The desired product was white solid obtained from precipitation using CH₂Cl₂ and n-hexane (yield=60%).

### Example 4

### Synthesis of tfpytz

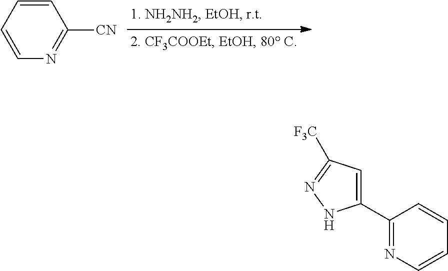 [SMILES: N#Cc1ccccn1 ; FC(F)(F)c1cc(-c2ccccn2)[nH]n1]

2-cyanopyridine (1.04 g, 10 mmol) was added to 25 ml round-bottom flask and completely dissolved with 5 ml ethanol. The NH₂NH₂ (0.96 g, 30 mmol) was then added and underwent reaction at room temperature for 6 hours. The original solution was then added with equal volume of water and extracted with ethyl ether to obtain a white solid, which was then rinsed with ethyl ether to obtain an intermediate product having higher purity. The obtained product ethyl trifluoroacetate (1 g) and 15 ml ethanol were added to 50 ml round-bottom flask with thermal reflux for 12 hours. After completion of reaction and removal of ethanol, the desired product was obtained as white solid by precipitation using n-hexane (yield=50%).

### Example 5

### Synthesis of pytz

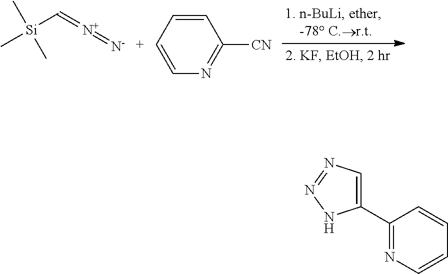

50 ml anhydrous ethyl ether and (Trimethylsilyl)diazomethane (6 mL, 12.0 mmol) were added to a 250 ml flask preheated to remove moisture and then purged with nitrogen gas. The mixture was added with BuLi reagent (6 mL, 14.4 mmol) allowed to react for 0.5 hr and then added with 2-Cyanopyridine (1.04 g, 10.0 mmol) allowed for react for 12 hours. The resulting solution was extracted by adding ethyl ether. The organic layer was the condensed to obtain a white solid. The white solid, KF (0.58 g, 10.0 mmol), 10 ml ethanol and several dips of HCl were added in sequence to a 50 ml flask and allowed react with thermal reflux for 2 hours. The mixture was then neutralized with saturated NaHCO₃ solution and extracted with ethyl ether to collect the organic layer. A white solid was obtained by condensation of the organic layer and further purified with gel filtration column to obtain the product (yield=60%).

### Example 6

### Preparation of Iridium Complexes

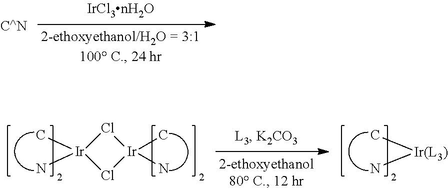

IrCl₃.nH₂O (0.375 g, 1.0 mmol) and the CAN ligand (2.2 mmol) was added to a round-bottom flask containing a mixture of 2-ethoxyethanol and water (3:1, v/v, 5 ml). The mixture was then stirred under nitrogen at 100° C. for 24 h and was cooled to room temperature. The precipitate formed was filtered and washed with H₂O, methanol, ether, and n-hexane. The solid was dried in vacuum to give the corresponding cyclometaled Ir^{III}-μ-chloro-bridged dimer (yield=72%). To a 25 mL flask were added the dimer complex, K₂CO₃ (0.152 g, 1.1 mmol), auxiliary ligand (1.1 mmol) and 2-ethoxyethanol (5 mL). The mixture was stirred at 80° C. under nitrogen atmosphere for 12 h. After cooling to room temperature, the mixture was filtered and the solid was collected and washed with methanol, ether, and n-hexane to give the desired iridium complex (yield=70-80%).

### Example 7

### fmoppy₂Ir(pic)

### Iridium(111)bis(2-(4-fluoro-2-methoxyphenyl)pyridinato-N,C^{2′}) (picolinate)

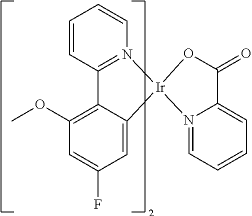

¹H NMR (400 MHz, CDCl₃)

δ 8.69 (d, J=5.6 Hz, 1H), 8.65 (d, J=8.4 Hz, 1H), 8.56 (d, J=8.4 Hz, 1H), 8.28 (d, J=7.6 Hz, 1H), 7.87 (t, J=7.6 Hz, 1H), 7.74 (d, J=5.2 Hz, 1H), 7.65 (t, J=7.6 Hz, 2H), 7.38 (d, J=5.6 Hz, 1H), 7.34 (t, J=6.4 Hz, 1H), 7.05 (t, J=6.8 Hz, 1H), 6.82 (t, J=6.4 Hz, 1H), 6.25 (d, J=11.2 Hz, 1H), 6.18 (d, J=10.0 Hz, 1H), 5.63 (d, J=8.8 Hz, 1H), 5.38 (d, J=7.2 Hz, 1H), 3.92 (s, 3H), 3.86 (s, 3H).

HRMS (FAB) m/z calcd for C₃₀H₂₂F₂IrN₃O₄ 719.1208; found M⁺ 719.1212.

### Example 8

### fmoppy₂Ir(pypz)

### Iridium(111)bis(2-(4-fluoro-2-methoxyphenyl)pyridinato-N,C^{2′}) (2-(1H-pyrazol-5-yl)pyridinate)

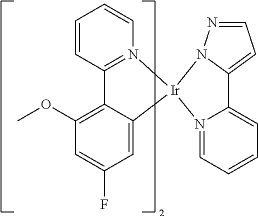

¹H NMR (400 MHz, CD₂Cl₂

δ 8.68 (d, J=8.8 Hz, 1H), 8.61 (d, J=8.4 Hz, 1H), 7.72-7.60 (m, 6H), 7.53 (d, J=2.0 Hz, 1H), 7.47 (d, J=5.6 Hz, 1H), 6.92-6.81 (m, 3H), 6.70 (d, J=2.0 Hz, 1H), 6.33 (dd, J=11.6, 2.4 Hz, 1H), 6.29 (dd, J=11.6, 2.4 Hz, 1H), 5.65 (dd, J=8.4, 2.4 Hz, 1H), 5.53 (dd, J=9.0, 2.4 Hz, 1H), 3.93 (s, 3H), 3.92 (s, 3H).

HRMS (FAB) m/z calcd for C₃₂H₂₄F₂IrN₅O₂ 741.1527; found M+741.1529.

### Example 9

### fmoppy₂Ir(tfpytz)

### Iridium(111)bis(2-(4-fluoro-2-methoxyphenyl)pyridinato-N,C^{2′}) (2-(3-(trifluoromethyl)-1,2,4-triazol-5-yl)pyridinate)

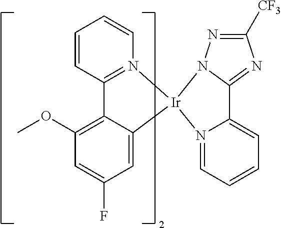

¹H NMR (400 MHz, CD₂Cl₂)

δ 8.71 (d, J=8.4 Hz, 1H), 8.64 (d, J=8.4 Hz, 1H), 8.22 (d, J=7.6 Hz, 1H), 7.89 (t, J=7.6 Hz, 1H), 7.77 (d, J=5.2 Hz, 1H), 7.70-7.65 (m, 3H), 7.48 (d, J=5.6 Hz, 1H), 7.20 (t, J=5.6 Hz, 1H), 6.91 (t, J=7.2 Hz, 1H), 6.85 (t, J=7.6 Hz, 1H), 6.37 (dd, J=12.0, 2.0 Hz, 1H), 6.34 (dd, J=11.8, 2.0 Hz, 1H), 5.59 (dd, J=8.6, 2.0 Hz, 1H), 5.53 (dd, J=8.8, 2.4 Hz, 1H), 3.95 (s, 3H), 3.94 (s, 3H).

HRMS (FAB) m/z calcd for C₃₂H₂₂F₅IrN₆O₂ 810.1354; found M⁺ 810.1343.

### Example 10

### fmoppy₂Ir(tfpypz)

### Iridium(111)bis(2-(4-fluoro-2-methoxyphenyl)pyridinato-N,C^{2′}) (2-(3-(trifluoromethyl)-1H-pyrazol-5-yl)pyridinate)

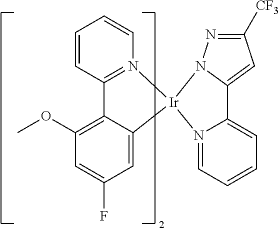

¹H NMR (400 MHz, CD₂Cl₂)

δ 8.71 (d, J=8.4 Hz, 1H), 8.62 (d, J=8.4 Hz, 1H), 7.75 (d, J=4.0 Hz, 2H), 7.70-7.63 (m, 3H), 7.56-7.55 (m, 2H), 7.02-6.98 (m, 1H), 6.97 (s, 1H), 6.90 (t, J=7.2 Hz, 1H), 6.84 (t, J=7.2 Hz, 1H), 6.35 (dd, J=8.8, 2.4 Hz, 1H), 6.32 (dd, J=9.0, 2.4 Hz, 1H), 5.58 (dd, J=8.4, 2.4 Hz, 1H), 5.53 (dd, J=8.6, 2.4 Hz, 1H), 3.94 (s, 6H). HRMS (FAB) m/z calcd for C₃₃H₂₃F₅IrN₅O₂ 809.1401; found M⁺ 809.1405.

### Example 11

### fmoppy₂Ir(pytz)

### Iridium(III)

### bis(2-(4-fluoro-2-methoxyphenyl)pyridinato-N,C^{2′}) (2-(3H-1,2,3-triazol-4-yl)pyridinate)

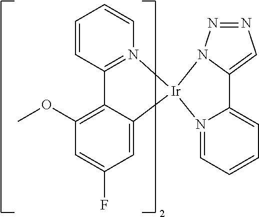

¹H NMR (400 MHz, CD₂Cl₂)

δ 8.70 (d, J=8.8 Hz, 1H), 8.64 (d, J=8.4 Hz, 1H), 8.12 (s, 1H), 7.81-7.75 (m, 2H), 7.72 (d, J=5.2 Hz, 1H), 7.67-7.63 (m; 2H), 7.56-7.53 (m, 2H), 7.01 (t, J=6.4 Hz, 1H), 6.86 (t, J=7.2 Hz, 1H), 6.82 (t, J=7.6 Hz, 1H), 6.36 (dd, J=11.4, 2.4 Hz, 1H), 6.33 (dd, J=11.8, 2.4 Hz, 1H), 5.64 (dd, J=8.4, 2.4 Hz, 1H), 5.56 (dd, J=8.8, 2.4 Hz, 1H), 3.95 (s, 3H), 3.94 (s, 3H).

HRMS (FAB) m/z calcd for C₃₁H₂₃F₂IrN₆O₂ 742.1480; found M⁺ 742.1477.

### Example 12

### Ir(fmoppy)₃

### fac-tris(2-(4-fluoro-2-methoxyphenyl)pyridinato-N,C^{2′}) Iridium(111)

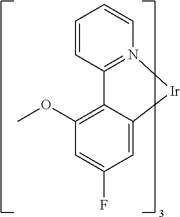

¹H NMR (400 MHz, CD₂Cl₂)

δ 8.72 (d, J=8.4 Hz, 3H), 7.63 (t, J=8.4 Hz, 3H), 7.44 (d, J=4.4 Hz, 3H), 6.84 (t, J=6.0 Hz, 3H), 6.25 (dd, J=11.2, 2.4 Hz, 3H), 6.09 (dd, J=9.2, 2.4 Hz, 3H), 3.92 (s, 9H).

HRMS (FAB) m/z calcd for C₃₆H₂₇F₃IrN₃O₃ 799.1634; found M⁺ 799.1622.

### Example 12

### Synthesis of (dpiq)₂Ir(acac)

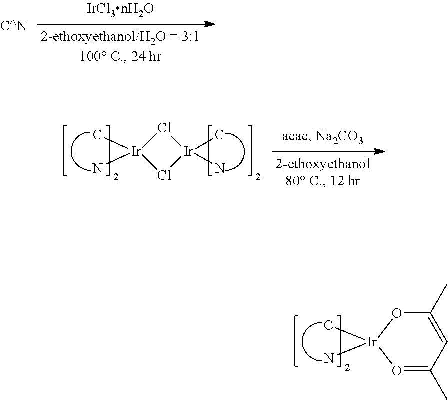

A similar procedure as that for (fmoppy)₂Ir(tfpypz) was employed for the synthesis of other iridium complexes. The compound (dpiq)₂Ir(acac) was obtained in 42% yield.

Referring to Table 1, the compounds of present invention have wavelengths of about 466˜488 nm and may be used for preparing red OLED, green OLED. Due to introduction of electron-donating methoxyl group at the phenyl group of CAN ligand, the radiance of fmoppy₂Ir(pic) has red-shift in comparison to that of FIrpic and HOMO of fmoppy₂Ir(pic) is enhanced. However, after the introduction of N̂N, the emission λₘₐₓ of the novel iridium complexes of the present invention is quite close to deep blue color in comparison to FIrpic. The quantum yield of iridium complexes of the present invention ranges from 7.9%˜29.5%, where complexes fmoppy₂Ir(tfpypz) and Ir(fmoppy)₃ have excellent capability in quantum yield.

TABLE 1
The measured physical properties of iridium
complexes

| | Absorption^{[a]} | | | LUMO/ |
|---|---|---|---|---|
| | λ (nm) {ε, | emission^{[b]}λₘₐₓ | Φ^{[c]} | HOMO |
| complex | 10³ M⁻¹ cm⁻¹} | (nm) | (%) | (eV)^{[d]} |
| FIrpic | 256(53.0), 319(16.2), | 498 | 33.4 | 2.90/5.80 |
| | 380(6.5), 420(2.8) | | | |
| fmoppy₂Ir(pic) | 264(45.9), 316(26.0), | 476 | 12.2 | 2.91/5.64 |
| | 382(6.7), 426(2.8) | | | |
| fmoppy₂Ir(pypz) | 267(55.1), 314(35.4), | 472 | 14.4 | 2.62/5.44 |
| | 381(9.2), 412(3.2) | | | |
| fmoppy₂Ir(tfpytz) | 263(48.0), 325(27.3), | 466 | 7.9 | 2.79/5.67 |
| | 375(8.0), 407(3.1) | | | |
| fmoppy₂Ir(tfpypz) | 264(54.3), 312(33.6), | 468 | 24.2 | 2.70/5.55 |
| | 377(8.3), 408(3.1) | | | |
| fmoppy₂Ir(pytz) | 268(56.3), 325(31.5), | 468 | 15.9 | 2.70/5.58 |
| | 380(7.8), 407(3.2) | | | |
| | 264(54.5), 302(43.0), | | | |
| Ir(fmoppy)₃ | 352(22.0), 392(11.5), | 488 | 29.5 | 2.58/5.24 |
| | 432(3.3) | | | |

^{[a]}UV-vis absorption measured in CH₂Cl₂ at room temperature with ε in M⁻¹ cm⁻¹, and solution concentration = 1 × 10⁻⁵ M.
^{[b]}Photoluminescence measured in CH₂Cl₂ at room temperature, solution concentration = 1 × 10⁻⁴ M.
^{[c]}Measured in degassed CH₂Cl₂ relative to Cumarin (Φ = 0.99).
^{[d]}Redox measurement were carried out in CH₂Cl₂, solution concentration = 1 × 10⁻³ M; values are reported relative to Cp₂Fe/Cp₂Fe⁺.

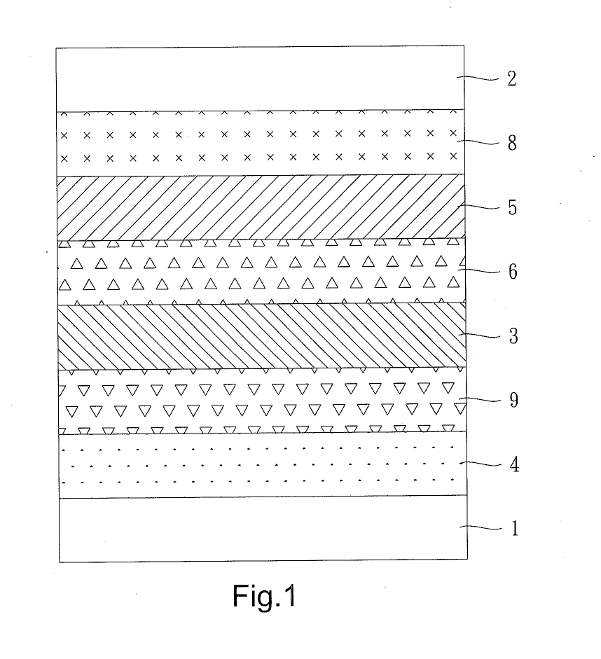

Refer to FIG. 1, which is a schematic diagram illustrating an organic light emitting device containing the iridium complex according to one embodiment of the present invention. The light emitting device includes an emitting layer 3 configured between the anode 1 and cathode 2. The emitting layer 3 is made of host emitting material doped with light emitting material. The light emitting device may also include a hole transport layer 4, an electron blocking layer 9, an emitting layer 3, an hole blocking layer 6, an electron transport layer 5 and an electron injecting layer 8 sequentially configured on top of the anode 1. The real thickness of each layer doesn't correspond to the schematic size, and electron blocking layer 9, hole blocking layer 6 and electron injecting layer 8 may be optional. It is noted that the iridium complex of the present invention may be a host emitting material or a dopant in the emitting layer.

In the tested electroluminescent devices, the substrate is made of ITO, and tested anode electrode materials include LiF/Al. Tested emitting materials in the emitting layer (EML) include iridium complexes. BCP (2,9-dimethyl-4,7-diphenyl-[1,10]phenanthroline), Alga (tris(8-hydroxyquinoline)aluminum(III), TAZ(3-(4-biphenyl)-4-phenyl-5-(4-tert-butyl phenyl)-1,2,4-triazole) and TPBI (1,3,5-tris(N-phenyl-benzimidizol-2yl) benzene) are used as electron transporting materials in the electron transport layer (ETL). The tested hole transporting materials in the hole transporting layer (HTL) include NPB (4,4′-bis[N-(1-naphthyl)-N-phenyl-amino]biphenyl), TCTA (4,4′,4″-tri(N-carbazolyl)triphenylamine) and mCP(N,N′-dicarbazolyl-3,5-benzene). The detailed structures of the tested devices are as follows:

1A: TCTA(30)/mCP(20)/BSB: fmoppy₂Ir(pic) (6%)(30)/BCP(10)/Alq(30)
1B: TCTA(30)/mCP(20)/BSB: fmoppy₂Ir(pic)(8%)(30)/BCP(10)/Alq(30)
1C: NPB(30)/TCTA(20)/CzSi: fmoppy₂Ir(pic)(8%)(25)/TAZ(50)
1D: NPB(30)/TCTA(20)/CzSi: fmoppy₂Ir(pic)(8%)(25)/TPBI(50)
1E: NPB(30)/TCTA(20)/CzSi: fmoppy₂Ir(pic)(8%)(25)/BSB(10)/TAZ(40)
1F: NPB(30)/TCTA(20)/CzSi: fmoppy₂Ir(pypz)(8%)(25)/TAZ(50)
1G: NPB(30)/TCTA(20)/CzSi: fmoppy₂Ir(tfpytz)(8%)(25)/TAZ(50)
1H: NPB(30)/TCTA(20)/CzSi: fmoppy₂Ir(tfpypz)(8%)(25)/TAZ(50)
1I: NPB(30)/TCTA(20)/CzSi: fmoppy₂Ir(pytz)(8%)(25)/TAZ(50)

### 1J: NPB(30)/TCTA(20)/CzSi: Ir(fmoppy)₃(8%)(25)/TAZ(50)

H TCTA(30)/mCP(20)/BSB: FIrpic(6%)(30)/BCP(10)/Alq(30)
Anode: Al/LiF; Structure thickness unit: nm.

TABLE 2
Comparison of the performance of the
electroluminescent devices

| | V_{d}^{a} | Lₘₐₓ^{b} | ηₑₓₜ^{c} | η_{c}^{d} | ηₚ^{e} | λₘₐₓ | |
|---|---|---|---|---|---|---|---|
| Device | [V] | [cd/m², V] | [%, V] | [cd/A, V] | [lm/W, V] | [nm] | CIE @8 V |
| 1A | 5.0 | 11741, | 17.4, 7.5 | 37.3, 7.5 | 16.5, 7.0 | 476 | (0.14, |
| | | 13.5 | | | | | 0.36) |
| 1B | 5.7 | 14439, | 11.8, 8.5 | 26.9, 8.5 | 10.4, 8.0 | 476 | (0.15, |
| | | 14.5 | | | | | 0.38) |
| 1C | 4.0 | 20172, | 12.0, 5.5 | 25.0, 5.5 | 16.8, 4.5 | 476 | (0.13, |
| | | 14.0 | | | | | 0.35) |
| 1D | 3.7 | 23848, | 9.1, 5.0 | 18.7, 5.0 | 12.3, 4.5 | 476 | (0.12, |
| | | 12.5 | | | | | 0.35) |
| 1E | 4.0 | 20431, | 9.0, 5.5 | 19.4, 5.5 | 13.0, 4.5 | 476 | (0.13, |
| | | 13.5 | | | | | 0.36) |
| 1F | 3.6 | 26452, | 17.5, 5.0 | 32.8, 5.0 | 24.6, 4.0 | 472 | (0.12, |
| | | 13.5 | | | | | 0.30) |
| 1G | 4.0 | 7328, | 9.1, 4.5 | 14.7, 4.5 | 10.3, 4.5 | 468 | (0.12, |
| | | 10.0 | | | | | 0.26) |
| 1H | 3.7 | 8304, | 11.6, 4.5 | 19.9, 4.5 | 14.3, 4.0 | 470 | (0.13, |
| | | 13.5 | | | | | 0.26) |
| II | 3.4 | 11761, | 11.0, 3.5 | 20.2, 3.5 | 18.2, 3.5 | 470 | (0.13, |
| | | 11.5 | | | | | 0.28) |
| 1J | 3.6 | 43038, | 16.2, 5.0 | 36.8, 5.0 | 28.4, 4.0 | 482 | (0.12, |
| | | 13.5 | | | | | 0.41) |
| H | 5.1 | 11000, | 14.3, 8.5 | 33.5, 8.0 | 14.8, 6.5 | 498 | (0.17, |
| | | 18.0 | | | | | 0.41) |

^{a}Driving voltage (V_{d}).
^{b}Maximum luminescence (Lₘₐₓ).
^{c}Maximum external quantum efficiency (ηₑₓₜ).
^{d}Maximum current efficiency (η_{c}).
^{e}Maximum power efficiency (ηₚ).

Referring to Table 2, Devices 1A and H have the same device configuration adopting hole blocking material BSB (4,4′-bis-triphenylsilanyl-biphenyl) and dopant concentration. In comparison to device H adopting FIrpic as host emitter, device 1A adopting fmoppy₂Ir(pic) have better performance in efficiency and luminescence and have (0.14, 0.36) in CIE coordination. Devices 1C-1J adopt CzSi (9-(4-tert-butylphenyl)-3,6-bis(triphenyl silyl)-9H-carbazole) instead of BSB used in device 1A and 1B. Among these devices, devices 1F and 1J respectively fmoppy₂Ir(pypz) and Ir(fmoppy)3 show good performance, where device 1F has 17.5% ηₑₓₜ, 32.8 cd/A η_{c} and 24.6 lm/w ηₚ and device 1J has 16.2% ηₑₓₜ, 36.8 cd/A η_{c} and 28.4 lm/w ηₚ. Therefore, fmoppy₂Ir(pypz) and Ir(fmoppy)₃ show great potential as blue host emitters and dopants.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. An iridium complex represented by the following formula: 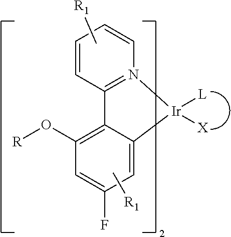
wherein each R₁ is independently hydrogen or a C₁-C₆ alkyl group, a C₁-C₆ alkoxy group, a hydroxyl group or a halogen, R is C1-C20 alkyl, C2-C20 alkenyl, C2-C20 alkynyl, C3-C20 cycloalkyl, C3-C20 cycloalkenyl, C1-C20 heterocycloalkyl, C1-C20 heterocycloalkenyl, aryl or heteroaryl; and
an auxiliary ligand is presented by L and X linked with an arch, and has formula of Ar₁-Ar₂, wherein Ar₁ and Ar₂ independently are an aromatic ring or N-heterocyclic ring, or Ar₁-Ar₂ together are 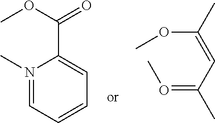
wherein L is N or O, and X is C, N or O.

2. The iridium complex as claimed in claim 1, represented by the following formula:

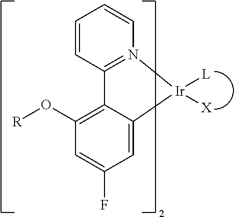

3. The iridium complex as claimed in claim 1, wherein R is C1-C20 alkyl.

4. The iridium complex as claimed in claim 1, represented by the following formula:

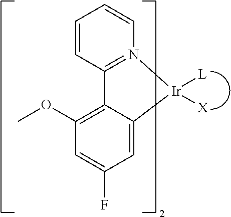

5. The iridium complex as claimed in claim 1, wherein the auxiliary ligand presented by L and X is represented with following formulae: 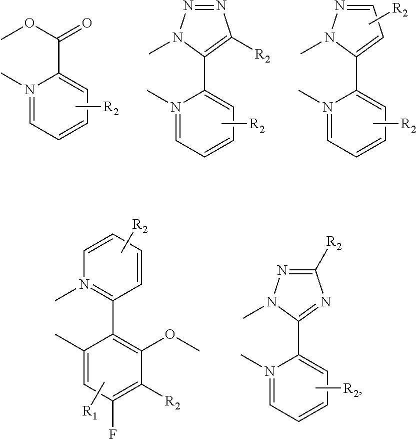
wherein R₂ is a member independently selected from the group consisting of hydrogen, halo, cyano, trifluoromethyl, amino, C1-C10 alkyl, C2-C10 alkenyl, C2-C10 alkynyl, C3-C20 cycloalkyl, C3-C20 cycloalkenyl, C1-C20 heterocycloalkyl, C1-C20 heterocycloalkenyl, aryl and heteroaryl.

6. The iridium complex as claimed in claim 1, wherein iridium complex is a member selected from the group consisting of fmoppy₂Ir(pic), fmoppy₂Ir(pypz), fmoppy₂Ir(tfpytz), fmoppy₂Ir(tfpypz), fmoppy₂Ir(pytz), Ir(fmoppy)₃ and fmoppy₂Ir(acac).

7. An organic light emitting diode, comprising:
a cathode;
an anode;
an emitting layer configured between the cathode and the anode, wherein the emitting layer comprises an iridium complex, the iridium complex is represented by the following formula: 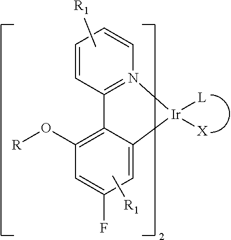
wherein each R₁ is independently hydrogen or a C₁-C₆ alkyl group, a C₁-C₆ alkoxy group, a hydroxyl group or a halogen, R is C1-C20 alkyl, C2-C20 alkenyl, C2-C20 alkynyl, C3-C20 cycloalkyl, C3-C20 cycloalkenyl, C1-C20 heterocycloalkyl, C1-C20 heterocycloalkenyl, aryl or heteroaryl; and
an auxiliary ligand is presented by L and X linked with an arch, and has formula of Ar₁-Ar₂, wherein Ar₁ and Ar₂ independently are an aromatic ring or N-heterocyclic ring, or Ar₁-Ar₂ together are 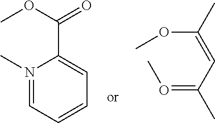
wherein L is N or O, and X is C, N or O.

8. The organic light emitting diode as claimed in claim 7, wherein the iridium complex is represented by the following formula:

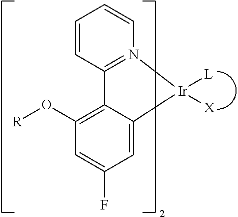

9. The organic light emitting diode as claimed in claim 7, wherein R is C1-C20 alkyl.

10. The organic light emitting diode as claimed in claim 7, wherein the iridium complex is represented by the following formula:

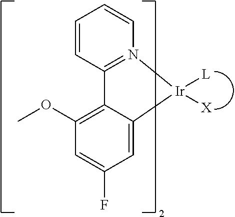

11. The organic light emitting diode as claimed in claim 7, wherein the auxiliary ligand presented by L and X is represented with following formulae: 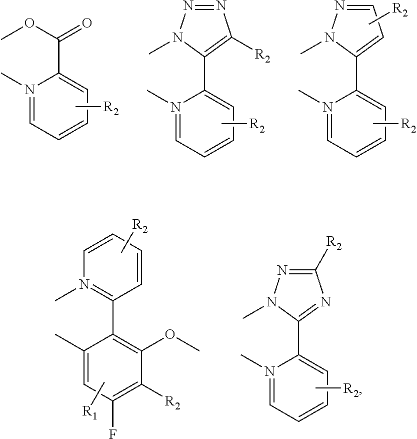
wherein R₂ is a member independently selected from the group consisting of hydrogen, halo, cyano, trifluoromethyl, amino, C1-C10 alkyl, C2-C10 alkenyl, C2-C10 alkynyl, C3-C20 cycloalkyl, C3-C20 cycloalkenyl, C1-C20 heterocycloalkyl, C1-C20 heterocycloalkenyl, aryl and heteroaryl.

12. The organic light emitting diode as claimed in claim 7, wherein iridium complex is a member selected from the group consisting of fmoppy₂Ir(pic), fmoppy₂Ir(pypz), fmoppy₂Ir(tfpytz), fmoppy₂Ir(tfpypz), fmoppy₂Ir(pytz), Ir(fmoppy)₃ and fmoppy₂Ir(acac).

13. The organic light emitting diode as claimed in claim 7, further comprising an electron transport layer.

14. The organic light emitting diode as claimed in claim 7, further comprising a hole transport layer.

15. The organic light emitting diode as claimed in claim 7, wherein the iridium complex is a host emitter.

16. The organic light emitting diode as claimed in claim 7, wherein the iridium complex is a dopant.

17. The organic light emitting diode as claimed in claim 7, wherein the organic light emitting diode is a blue phosphorescent OLED.
